(19) United States
(12) Patent Application Publication
(10) Pub. No.: US 2024/0313736 A1
(43) Pub. Date: Sep. 19, 2024

(54) TEMPERATURE COMPENSATED FILTER WITH INCREASED STATIC CAPACITANCE

(71) Applicant: Qorvo US, Inc., Greensboro, NC (US)

(72) Inventors: Casey Kirkpatrick, Jamestown, NC (US); Christian Huck, Munich (DE)

(21) Appl. No.: 18/387,244

(22) Filed: Nov. 6, 2023

Related U.S. Application Data
(60) Provisional application No. 63/490,243, filed on Mar. 14, 2023.

(51) Int. Cl. H03H 9/02; H03H 3/08; H03H 9/64

(52) U.S. Cl. CPC H03H 9/02834; H03H 3/08; H03H 9/02551; H03H 9/02574; H03H 9/6453

(57) ABSTRACT

A surface acoustic wave (SAW) device is provided with a piezoelectric substrate, an interdigitated transducer (IDT), and multiple dielectric layers. The IDT is over a top surface of the piezoelectric substrate and comprises first and second electrodes with interdigitated fingers. A first higher k dielectric layer is provided over the IDT, and a first lower k dielectric layer is provided over the first higher k dielectric layer. The dielectric constant of the first higher k dielectric layer is higher than the dielectric constant of the first lower k dielectric layer.

### RELATED APPLICATIONS

This application claims the benefit of provisional patent application Ser. No. 63/490,243, filed Mar. 14, 2023, the disclosure of which is hereby incorporated herein by reference in its entirety.

### FIELD OF THE DISCLOSURE

The present disclosure relates to acoustic wave devices, and particularly to surface acoustic wave (SAW) devices.

### BACKGROUND

Acoustic wave devices are widely used in modern electronics. At a high level, acoustic wave devices include a piezoelectric material in contact with one or more electrodes. Piezoelectric materials acquire a charge when compressed, twisted, or distorted, and similarly compress, twist, or distort when a charge is applied to them. Accordingly, when an alternating electrical signal is applied to the one or more electrodes in contact with the piezoelectric material, a corresponding mechanical signal (i.e., an oscillation or vibration) is transduced therein. Based on the characteristics of the one or more electrodes on the piezoelectric material, the properties of the piezoelectric material, and other factors such as the shape of the acoustic wave device and other structures provided on the device, the mechanical signal transduced in the piezoelectric material exhibits a frequency dependent on the alternating electrical signal. Acoustic wave devices leverage this frequency dependence to provide one or more functions.

Surface acoustic wave (SAW) devices, such as SAW resonators and SAW filters, are used in many applications such as radio frequency (RF) filters. For example, SAW filters are commonly used in receive and transmit paths of wireless RF front ends to realize filter applications, e.g. in duplexers or multiplexers. The widespread use of SAW filters is due to, at least in part, the fact that SAW filters exhibit low insertion loss with good rejection, can achieve broad bandwidths, and are a small fraction of the size of traditional cavity and ceramic filters. As the use of SAW filters in modern RF communication systems continues, there is a need for SAW filters with sharp transitions between desired passband frequencies and frequencies that are outside of desired passbands, as well as the need to reduce the size of the SAW devices while maintaining and/or improving their performance.

### SUMMARY

A surface acoustic wave (SAW) device is provided with a piezoelectric substrate, an interdigitated transducer (IDT), and multiple dielectric layers. The IDT is over a top surface of the piezoelectric substrate and comprises first and second electrodes with interdigitated fingers. A first higher k dielectric layer is provided over the IDT, and a first lower k dielectric layer is provided over the first higher k dielectric layer, where k is the relative dielectric constant. The dielectric constant of the first higher k dielectric layer is higher than the dielectric constant of the first lower k dielectric layer.

In one embodiment, first portions of the first higher k dielectric layer reside between adjacent ones of the interdigitated fingers of the first and second electrodes.

In one embodiment, first portions of the first higher k dielectric layer reside over the interdigitated fingers of the first and second electrodes, and second portions of the first higher k dielectric layer reside between adjacent ones of the interdigitated fingers of the first and second electrodes.

In one embodiment, a top surface of the first higher k dielectric layer is planar.

In one embodiment, a top surface of the first higher k dielectric layer is not planar and conformally covers the IDT.

In one embodiment, the SAW device further comprises a second higher k dielectric layer over the top surface of the piezoelectric substrate. The IDT and the first higher k dielectric layer reside over the second higher k dielectric layer. The dielectric constant of the second higher k dielectric layer is higher than the dielectric constant of the first lower k dielectric layer.

In one embodiment, the SAW device further comprises a second lower k dielectric layer between the top surface of the piezoelectric substrate and the first higher k dielectric layer. First portions of the first higher k dielectric layer reside over the interdigitated fingers of the first and second electrodes. First portions of the second lower k dielectric layer reside between adjacent ones of the interdigitated fingers of the first and second electrodes. The dielectric constant of the first higher k dielectric layer is higher than the dielectric constant of the second lower k dielectric layer.

In one embodiment, the SAW device further comprises a second higher k dielectric layer over the top surface of the piezoelectric substrate. The IDT, the second lower k dielectric layer, and the first higher k dielectric layer reside over the second higher k dielectric layer. The dielectric constant of the second higher k dielectric layer is higher than the dielectric constant of the first lower k dielectric layer.

In one embodiment, second portions of the second lower k dielectric layer reside over the interdigitated fingers of the first and second electrodes. A top surface of the second lower k dielectric layer is planar. A top surface of the first higher k dielectric layer is planar.

In one embodiment, a top surface of the second lower k dielectric layer is not planar and conformally covers the IDT.

In one embodiment, the SAW device further comprises a second higher k dielectric layer over the top surface of the piezoelectric substrate. The IDT, the second lower k dielectric layer, and the first higher k dielectric layer reside over the second higher k dielectric layer. A dielectric constant of the second higher k dielectric layer is higher than the dielectric constant of the first lower k dielectric layer. The top surface of the first higher k dielectric layer may not be planar, and as such, conformally cover the second lower k dielectric layer.

In one embodiment, the first higher k dielectric layer comprises hafnium oxide (HfO₂). The first lower k dielectric layer may comprise silicon dioxide (SiO₂).

In one embodiment, the dielectric constant of first higher k dielectric layer is greater than 4, and the dielectric constant of the first lower k dielectric layer is less than 4.

In one embodiment, the dielectric constant of first higher k dielectric layer is greater than 10, and the dielectric constant of the first lower k dielectric layer is less than 4.

In one embodiment, the dielectric constant of first higher k dielectric layer is greater than 24, and the dielectric constant of the first lower k dielectric layer is less than 4.

In one embodiment, the dielectric constant of first higher k dielectric layer is greater than 24.

In one embodiment, the first higher k dielectric layer comprises at least one of hafnium oxide, silicon nitride, yttrium oxide, zirconium oxide, lanthanum oxide, tantalum oxide, titanium oxide, and aluminum oxide.

In one embodiment, the SAW device is provided with a piezoelectric substrate, an IDT, and one or more dielectric layers. A first higher k dielectric layer resides over the substrate. The IDT resides over a top surface of the first higher k dielectric layer and comprises first and second electrodes with interdigitated fingers. A first lower k dielectric layer resides over the first higher k dielectric layer and the IDT, wherein the dielectric constant of the first higher k dielectric layer is higher than the dielectric constant of the first lower k dielectric layer.

A method of fabricating a SAW device is also provided. In one embodiment, the method may comprise:
providing a piezoelectric substrate;
providing an IDT over a top surface of the piezoelectric substrate and comprising first and second electrodes with interdigitated fingers;
providing a first higher k dielectric layer over the IDT; and
providing a first lower k dielectric layer over the first higher k dielectric layer, wherein a dielectric constant of first higher k dielectric layer is higher than a dielectric constant of the first lower k dielectric layer.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a perspective view illustration of a representative surface acoustic wave (SAW) device.

FIG. 2 is a top view of the SAW device of FIG. 1.

FIG. 3 is a cross-sectional view of a SAW device according to a first embodiment.

FIG. 4 is a cross-sectional view of a SAW device according to a second embodiment.

FIG. 5 is a cross-sectional view of a SAW device according to a third embodiment.

FIG. 6 is a cross-sectional view of a SAW device according to a fourth embodiment.

FIG. 7 is a cross-sectional view of a SAW device according to a fifth embodiment.

FIG. 8 is a cross-sectional view of a SAW device according to a sixth embodiment.

FIG. 9 is a cross-sectional view of a SAW device according to a seventh embodiment.

FIG. 10 is a cross-sectional view of a SAW device according to an eighth embodiment.

FIG. 11 is a cross-sectional view of a SAW device according to a ninth embodiment.

FIG. 12 is a cross-sectional view of a SAW device according to a tenth embodiment.

FIG. 13 is a cross-sectional view of a SAW device according to an eleventh embodiment.

FIG. 14 provides top down plots of real part of admittance Re(Y) (conductance), imaginary part of admittance Im(Y) (susceptance), phase of admittance Ph(Y), absolute value of admittance |Y|, Bode quality factor, and return loss |S₁₁| versus frequency (f) in MHz for a first embodiment.

FIG. 15 provides top down plots of real part of admittance Re(Y) (conductance), imaginary part of admittance Im(Y) (susceptance), phase of admittance Ph(Y), absolute value of admittance |Y|, Bode quality factor, and return loss |S₁₁| versus frequency (f) in MHz for a second embodiment.

FIG. 16 is a plot of size reduction of acoustic area (%) versus frequency (f) in MHz.

FIG. 17 is a block diagram of a user element in which the concepts of the present disclosure may be employed.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The present disclosure relates to a surface acoustic wave (SAW) device comprising a piezoelectric substrate with at least one interdigitated transducer (IDT) on a top surface of the piezoelectric substrate. A combination of lower and higher dielectric layers is provided over the top surface of the piezoelectric substrate to increase static capacitance and provide temperature compensation for the SAW device. In one embodiment, a SAW device is provided with a piezoelectric substrate, an IDT, and multiple dielectric layers. The IDT is over a top surface of the piezoelectric substrate and comprises first and second electrodes with interdigitated fingers. A first higher k dielectric layer is provided over the IDT, and a first lower k dielectric layer is provided over the first higher k dielectric layer. The dielectric constant of the first higher k dielectric layer is higher than the dielectric constant of the first lower k dielectric layer.

In another embodiment, a SAW device is provided with a piezoelectric substrate, an IDT, and one or more dielectric layers. A first higher k dielectric layer resides over the substrate. The IDT resides over a top surface of the first higher k dielectric layer and comprises first and second electrodes with interdigitated fingers. A first lower k dielectric layer resides over the first higher k dielectric layer and the IDT, wherein a dielectric constant of first higher k dielectric layer is higher than the dielectric constant of the first lower k dielectric layer.

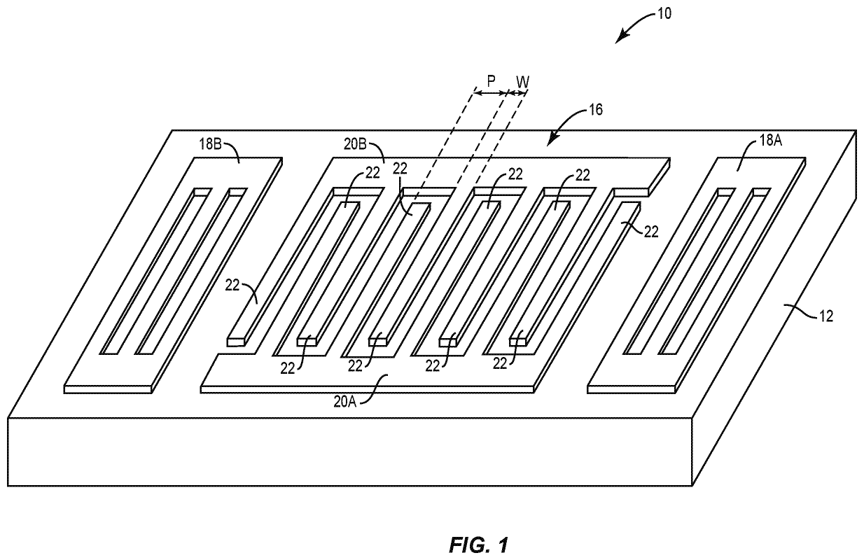

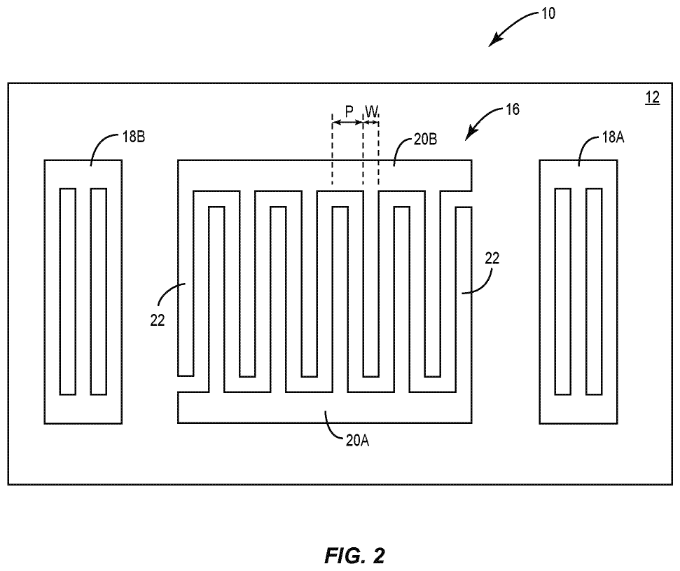

Before describing the details of the present disclosure further, a general description of the core elements of an exemplary SAW device is provided. FIGS. 1 and 2 are isometric and top views of a representative SAW device 10, which is configured as a SAW resonator. The SAW device 10 includes a piezoelectric substrate 12, an IDT 16 on a top surface of the piezoelectric substrate 12, a first reflector structure 18A on the top surface of the piezoelectric substrate 12 adjacent to the IDT 16, and a second reflector structure 18B on the top surface of the piezoelectric substrate 12 adjacent to the IDT 16 opposite the first reflector structure 18A. As is well known, the SAW device 10 may be connected to other resonators on a die to form a more complex device like a filter. Also, it is understood that FIGS. 1 and 2 are only simplified representations of SAW devices 10. Such resonators may be more complicated comprising additional features. For example, the period between the electrodes or their polarity can vary along the transducer. In addition, only one-port resonators are represented, i.e. one transducer between two reflectors. Coupled resonator filters (CRF) can be designed by inserting several transducers between reflectors, these transducers being connected to separated electrical ports (typically input and output ports). Several of these CRFs may be connected together or connected to one-port resonators to form a device (normally a filter or a duplexer). Additionally, several geometric features may be added to the IDT to suppress unwanted spurious modes like e.g. transverse modes. Even if these devices are not specifically described, it is understood that they are within the scope of the present disclosure.

The exemplary IDT 16 includes a first electrode 20A and a second electrode 20B, each of which includes a number of electrode fingers 22 that are interleaved with one another as shown. A lateral spacing of adjacent electrode fingers 22 of the first electrode 20A and the second electrode 20B defines an electrode pitch P of the IDT 16. The electrode pitch P may at least partially define a center frequency wavelength A of the SAW device 10, where the center frequency is the primary frequency of mechanical waves generated in the piezoelectric substrate 12 by the IDT 16. A finger width W of the adjacent electrode fingers 22 over the electrode pitch P may define a metallization ratio, or duty factor (DF), of the IDT 16, which will dictate certain operating characteristics of the SAW device 10, as will be appreciated by those skilled in the art.

In operation, an alternating electrical input signal provided at the first electrode 20A is transduced into a mechanical signal in the piezoelectric substrate 12, resulting in one or more acoustic waves therein. In the case of the SAW device 10, the resulting acoustic waves are predominately surface acoustic waves. As discussed above, due to the electrode pitch P, the metallization ratio of the IDT 16, the characteristics of the material of the piezoelectric substrate 12, and other factors, the magnitude and frequency of the acoustic waves transduced in the piezoelectric substrate 12 are dependent on the frequency of the alternating electrical input signal. This frequency dependence is often described in terms of changes in the impedance and/or a phase shift between the first electrode 20A and the second electrode 20B with respect to the frequency of the alternating electrical input signal.

An alternating electrical potential between the first and second electrodes 20A and 20B creates an electrical field in the piezoelectric material, which generates acoustic waves. The acoustic waves travel at the surface and eventually are transferred back into an electrical signal between the first and second electrodes 20A and 20B. The first reflector structure 18A and the second reflector structure 18B reflect the acoustic waves in the piezoelectric substrate 12 back towards the IDT 16 to confine the acoustic waves longitudinally in the area surrounding the IDT 16. FIG. 2 is a top view of the SAW device 10.

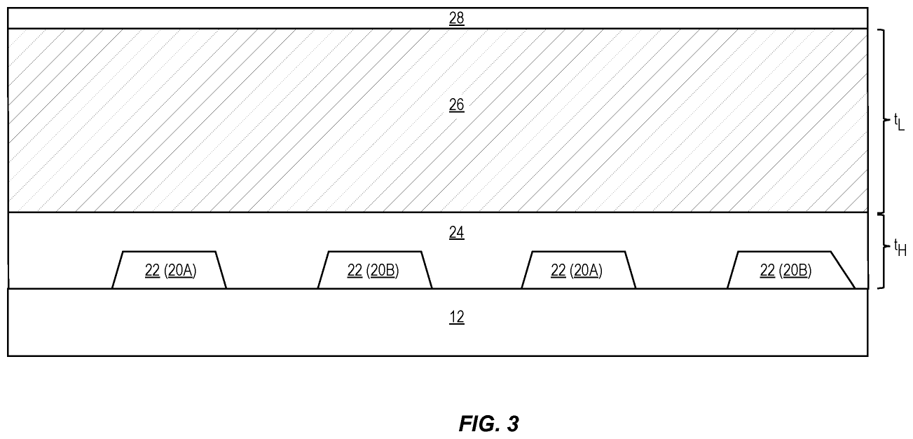

FIG. 3 is a cross-sectional view of a SAW device 10 according to a first embodiment. The first and second electrodes 20A and 20B are formed over the piezoelectric substrate 12 and from an electrode stack, which may include one or more electrically conductive layers. For example, an electrode stack may have a first adhesion layer on the piezoelectric substrate, a conducting metal layer on the first adhesion layer, and a second adhesion layer on the conducting metal layer. In one exemplary configuration, the first adhesion layer is titanium (Ti), the conducting metal layer is copper (Cu), and the second adhesion layer is aluminum (Al). The first and second adhesion layers facilitate adhesion of adjacent layers. If the piezoelectric substrate 12 is lithium niobate, LiNbO₃ (LN), the piezoelectric cut angle may be 127 degrees YX. This means that the substrate orientation is defined by starting from a plane with a normal that is the Y axis of the crystal and rotating this axis by 127 degrees around the X axis of the crystal. Lithium tantalate, LiTaO (LT) is another common piezoelectric substrate material. The cut angles may vary depending on the application, piezoelectric substrate materials, and configurations of the first and second electrodes 20A, 20B. The electrode stack for the first and second electrodes 20A and 20B may take on various forms and is not limited to that described above. For example, the electrode stack may take the forms of the various electrode stacks disclosed in U.S. provisional patent application No. 63/435,083, filed Dec. 23, 2022, which describes electrode stacks including heavy metal temperature compensated (TC) SAW (HM-TCSAW) stacks, and is incorporated herein by reference in its entirety.

One or more dielectric overcoat layers are provided over the first and second electrodes 20A and 20B and remaining portions of the piezoelectric substrate 12. As described in detail below, at least one dielectric overcoat layer provides a temperature compensation layer to improve stability over temperature by its positive temperature coefficient of frequency (TCF), which compensates for the negative TCF of the piezoelectric substrate 12 and other materials in the SAW device 10. At least one of the dielectric layers increases the static capacitance associated with the SAW device 10.

For the embodiment of FIG. 3, a first higher k dielectric layer 24 and a first lower k dielectric layer 26 are employed. The first higher k dielectric layer 24 is provided over the top surface of the piezoelectric substrate 12 and the first and second electrodes 20A and 20B of the IDT 16 as well as the first and second reflectors 18A and 18B. For all embodiments, the additional higher k dielectric layers may be added over the entire resonator (IDT and reflectors) or only the IDT 16. The first higher k dielectric layer 24 has portions between the adjacent fingers 22 of the first and second electrodes 20A and 20B as well as over top of the fingers 22. The first lower k dielectric layer 26 is provided over the top surface of the first higher k dielectric layer 24.

The first higher k dielectric layer 24 has a dielectric constant greater than that of the first lower k dielectric layer 26. The first higher k dielectric layer 24 is intended to increase the static capacitance associated with and provided between the fingers 22 of the first and second electrodes 20A and 20B. The first lower k dielectric layer 26 provides the positive TCF to compensate for the negative TCF of the piezoelectric substrate 12 and other materials in the SAW device 10. In one embodiment, the first lower k dielectric layer 26 has a dielectric constant k less than 4 (k<4), and the first higher k dielectric layer 24 has a dielectric constant k greater than 4 (k>4). In other embodiments, the first higher k dielectric layer 24 has a dielectric constant greater than 6 (k>6), greater than 10 (k>10), greater than 20 (k>20), or greater than 24 (k>24).

The first lower k dielectric layer 26 may be formed from silicon dioxide (SiO₂), doped SiO₂, or the like. The first higher k dielectric layer 24 may be formed from hafnium oxide (HfO₂, K˜25), silicon nitride (Si₃N₄, k˜7), yttrium oxide (Y2O3, k˜15), zirconium oxide (ZrO2, k˜25), lanthanum oxide (La2O3 k˜30), tantalum oxide (Ta2O5, k˜26), titanium oxide (TiO2, k˜80), aluminum oxide (Al2O3, k˜9), or the like. Either of these layers may be formed using, chemical vapor deposition, physical vapor deposition, atomic layer deposition, or the like. The embodiments described below include one or more additional lower and/or higher k dielectric layers, which may be formed in the same way and with the same respective materials as those just identified, unless specifically noted otherwise.

A passivation layer 28 may be formed over the first lower k dielectric layer 26 for passivation and/or trimming. The passivation layer 28 may be formed from SiO₂, silicon nitride (Si₃N₄), or the like.

For fabrication, the IDTs 16 are formed over the top surface of the piezoelectric substrate 12. The first higher k dielectric layer 24 is conformally formed over the top surface of the piezoelectric substrate 12 and the IDT 16. The first higher k dielectric layer 24 may be planarized to provide a planar top surface using a chemical-mechanical polish (CMP) or like process. The first lower k dielectric layer 26 is then formed over the planar top surface of the first higher k dielectric layer 24. The passivation layer 28 is then formed over the top surface of the first lower k dielectric layer 26.

When HfO₂ is employed for the first higher k dielectric layer 24, the high relative dielectric constant of HfO₂ increases the static capacitance between the first and second electrodes 20A and 20B of the IDT 16 when compared to a similar geometry that only uses a dielectric overcoat of SiO₂, which enables acoustic area reduction in filter circuits. When SiO2 is employed as the first lower k dielectric layer 26, the positive temperature coefficient of frequency (TCF) of SiO₂ counters the negative TCF of the piezoelectric substrate 12, the metals in the electrode stack, and HfO₂ of the first higher k dielectric layer 24, resulting in temperature compensation for the filter circuits. The thickness of the first higher k dielectric layer 24, t_{H}, is variable and adds an additional degree of freedom to resonator design. As thickness increases, static capacitance increases while the electromechanical coupling coefficient k2e is reduced. Filter designs have a wide range of bandwidth requirements allowing for t_{H} and resulting k2e to be tailored to band specific design requirements for maximum die size reduction. The thickness of the first lower dielectric k layer, t_{L}, is also variable to modulate and/or control the temperature coefficient of frequency (TCF) and electromechanical coupling coefficient k2e of the filter using the SAW device 10. In addition to the mentioned material related design parameters, SAW design parameters like pitch, duty factor (DF), electrode stack composition, metal thicknesses, and piezoelectric cut angles of the piezoelectric substrate 12 may be used for optimization.

Exemplary ranges for thicknesses for t_{L} are between 0.1 um and 0.5 um, and 0.5 um and 2 um. Exemplary ranges for thicknesses for t_{H} are between 0.1 um and 0.35 um, and 0.35 and 0.8 um. These ranges are merely exemplary and apply to the embodiment of FIG. 3 as well as the embodiments described below.

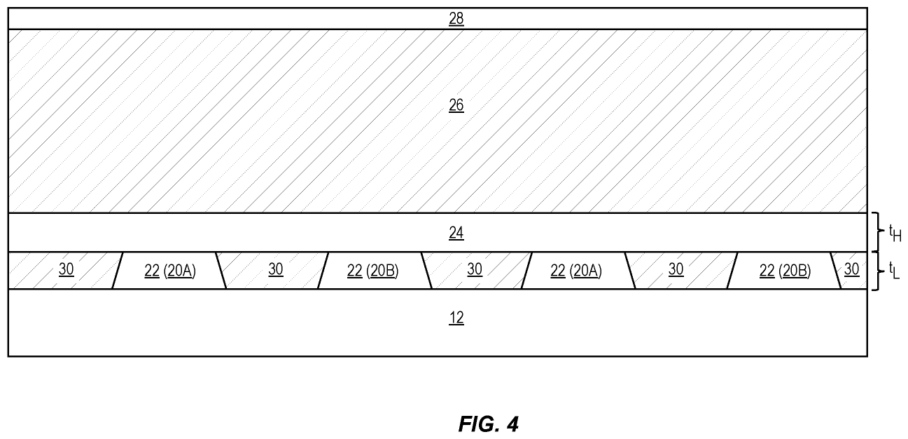

A second embodiment is shown in FIG. 4, wherein a precursor of the SAW device 10 includes the piezoelectric substrate 12 with an IDT 16. The fingers 22 of the first and second electrodes 20A and 20B of the IDT 16 are depicted. Following formation of the first and second electrodes 20A and 20B, a lower k dielectric layer 30 is deposited over the top surface of the piezoelectric substrate 12. The material of the lower k dielectric layer 30 fills in between the fingers 22 of the first and second electrodes 20A and 20B. The top surface of the lower k dielectric layer 30 is planarized such that the top surface of the lower k dielectric layer 30 is at or near the level of the top surfaces of the first and second electrodes 20A and 20B.

Next, the higher k dielectric layer 24 is formed over the top surface of the lower k dielectric layer 30 and the first and second electrodes 20A and 20B of the IDT 16. Another lower k dielectric layer 26 is then formed over the top surface of the higher k dielectric layer 24. The passivation layer 28 is then formed over the top surface of the lower k dielectric layer 26.

This embodiment may simplify fabrication as it may not require planarization of the higher k dielectric layer 24. Additionally, this structure can improve TCF if degraded too much according to the primary embodiment. The thickness, t_{H}, of the higher k dielectric layer 24 and its height position are design parameters for optimization in this embodiment. The thickness and composition of the lower k dielectric layer 26 may also be a design parameter.

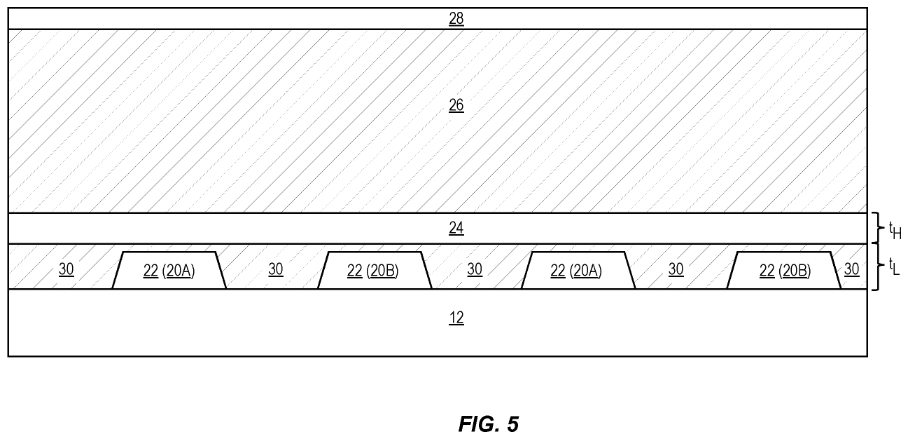

A third embodiment is shown in FIG. 5, which is similar to the embodiment provided in FIG. 4 with the exception that the lower k dielectric layer 30 covers the top surfaces of the fingers 22 of the first and second electrodes 20A and 20B. Again, a precursor of the SAW device 10 includes the piezoelectric substrate 12 with an IDT 16. The fingers 22 of the first and second electrodes 20A and 20B of the IDT 16 are depicted. Following formation of the first and second electrodes 20A and 20B, a lower k dielectric layer 30 is deposited between and over the fingers 22 of the first and second electrodes 20A and 20B. The top surface of the lower k dielectric layer 30 is planarized such that the top surface of the lower k dielectric layer 30 is above that of the top surfaces of the first and second electrodes 20A and 20B. The top surfaces of the first and second electrodes 20A and 20B are covered by at least a thin layer of the lower k dielectric layer 30.

Next, the higher k dielectric layer 24 is formed over the top surface of the lower k dielectric layer 30. Another lower k dielectric layer 26 is then formed over the top surface of the higher k dielectric layer 24. The passivation layer 28 is then formed over the top surface of the lower k dielectric layer 26.

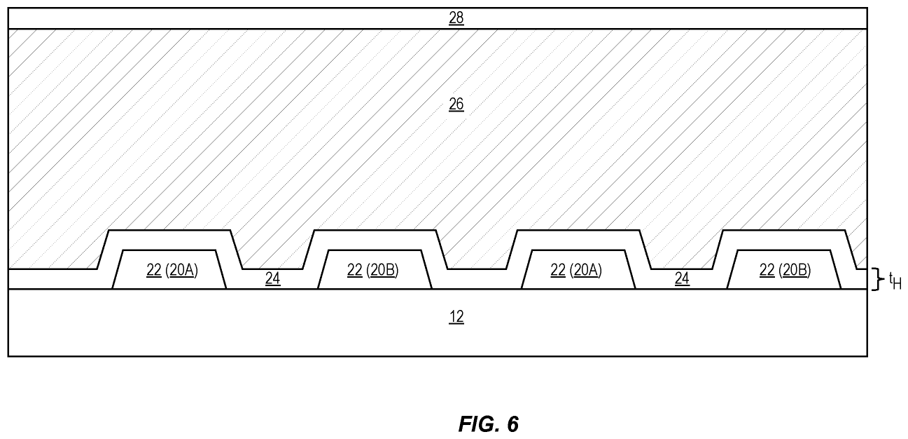

A fourth embodiment is shown in FIG. 6, which is similar to the embodiment provided in FIG. 3 with the exception that the higher k dielectric layer 24 conformally covers the top surface of the piezoelectric substrate 12 and the fingers 22 of the first and second electrodes 20A and 20B. Again, a precursor of the SAW device 10 includes the piezoelectric substrate 12 with an IDT 16. The fingers 22 of the first and second electrodes 20A and 20B of the IDT 16 are depicted. Following formation of the first and second electrodes 20A and 20B, the higher k dielectric layer 24 is deposited between and over the fingers 22 of the first and second electrodes 20A and 20B. In this configuration, the top surface of the higher k dielectric layer 24 does not need to be planarized. As such, the top surface of the higher k dielectric layer 24 follows conformally the contours of the top surface of the piezoelectric substrate 12 and the first and second electrodes 20A and 20B of the IDT 16. The top surfaces of the first and second electrodes 20A and 20B are covered by the higher k dielectric layer 24.

Next, the lower k dielectric layer 26 is formed over the contoured top surface of the higher k dielectric layer 24. A chemical mechanical polishing (CMP) process may be added to planarize the lower k dielectric layer 26. Next, the passivation layer 28 is then formed over the top surface of the lower k dielectric layer 26. The lower k dielectric layer 26 may be planarized before forming the passivation layer 28 over the surface of the lower k dielectric layer 26.

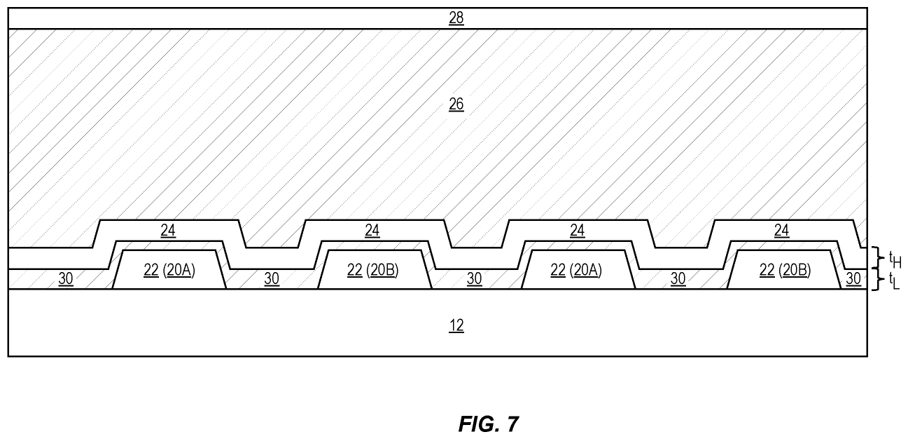

A fifth embodiment is shown in FIG. 7, wherein lower and higher k dielectric layers 30 and 24, respectively, conformally cover the top surface of the piezoelectric substrate 12 and the fingers 22 of the first and second electrodes 20A and 20B.

The precursor of the SAW device 10 includes the piezoelectric substrate 12 with an IDT 16. The fingers 22 of the first and second electrodes 20A and 20B of the IDT 16 are depicted. Following formation of the first and second electrodes 20A and 20B, the lower k dielectric layer 30 is conformally deposited between and over the fingers 22 of the first and second electrodes 20A and 20B. Next, the higher k dielectric layer 24 is conformally deposited over the lower k dielectric 30. Neither of these lower and higher k dielectric layers 30 and 24 are planarized. Next, the lower k dielectric layer 26 is formed over the contoured top surface of the higher k dielectric layer 24. The lower k dielectric layer 26 may be planarized before forming the passivation layer 28 over the surface of the lower k dielectric layer 26.

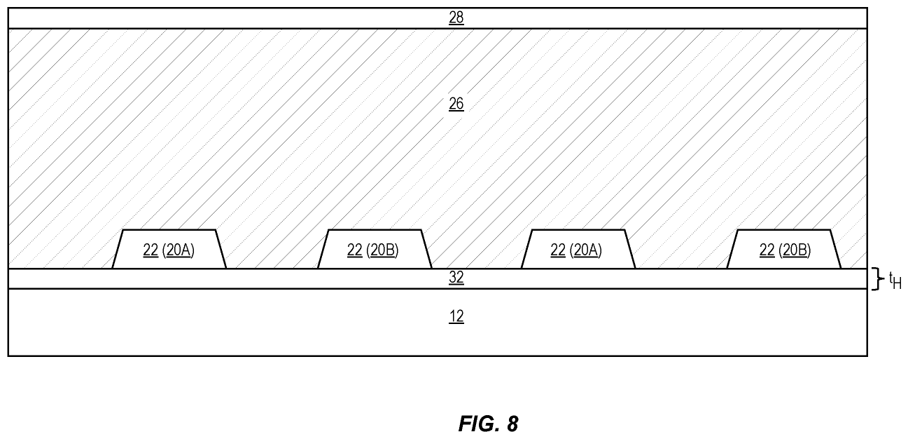

FIGS. 8-13 illustrate various embodiments wherein a higher k dielectric layer 32 is deposited over the piezoelectric substrate 12 prior to forming the first and second electrodes 20A and 20B of the IDT 16. Once the higher k dielectric layer 32 is deposited, the first and second electrodes 20A and 20B are formed on the higher k dielectric layer 32.

For the embodiment of FIG. 8, the lower k dielectric layer 26 is then formed over the first and second electrodes 20A and 20B and the exposed surfaces of the higher k dielectric layer 32 that are between the first and second electrodes 20A and 20B. The lower k dielectric layer 26 may be planarized prior to forming the passivation layer 28 over the lower k dielectric layer 26.

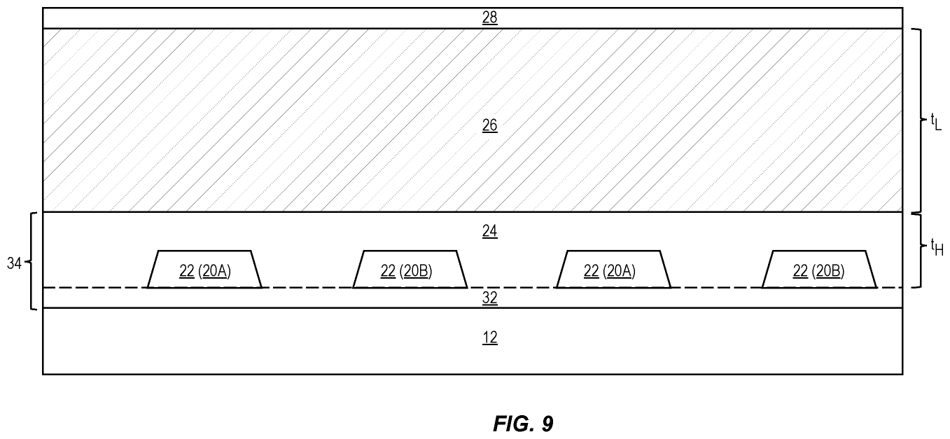

For the embodiment of FIG. 9, another higher k dielectric layer 24 is deposited over the first and second electrodes 20A and 20B and the exposed surfaces of the higher k dielectric layer 32 that are between the first and second electrodes 20A and 20B. At this point, all or at least significant portions of the fingers of the first and second electrodes 20A and 20B are completely or at least substantially encapsulated by the higher k dielectric material of the higher k dielectric layers 24, 32, which collectively may be referred to as a composite higher k layer 34. The higher k dielectric layer 24 may be planarized prior to forming the lower k dielectric layer 26 and passivation layer 28 over the higher k dielectric layer 24.

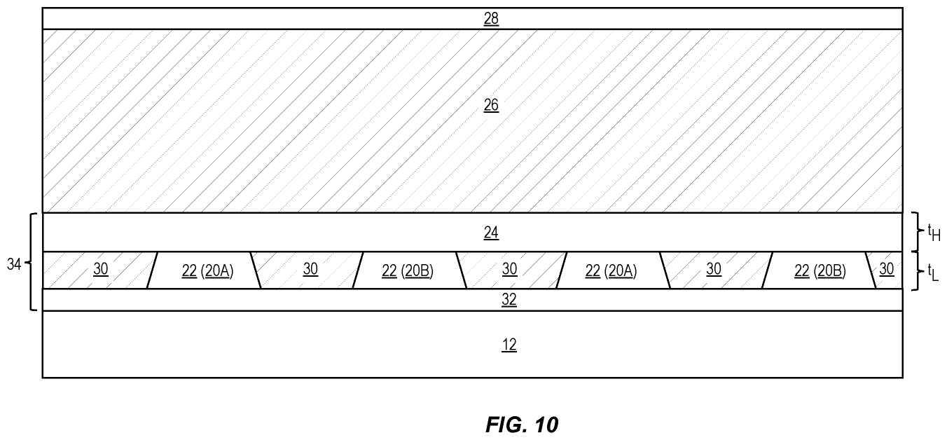

For the embodiment of FIG. 10, following formation of the first and second electrodes 20A and 20B, a lower k dielectric layer 30 is deposited over the first and second electrodes 20A and 20B and the exposed surfaces of the higher k dielectric layer 32 that are between the first and second electrodes 20A and 20B. The lower k dielectric layer 30 may be planarized to expose the top surfaces of the first and second electrodes 20A and 20B, such that the top surface of the lower k dielectric layer 30 is at or near the level of the top surface of the first and second electrodes 20A and 20B. The material of the lower k dielectric layer 30 fills in between the fingers 22 of the first and second electrodes 20A and 20B in this embodiment.

Next, the higher k dielectric layer 24 is formed over the top surface of the lower k dielectric layer 30 and the first and second electrodes 20A and 20B of the IDT 16. Another lower k dielectric layer 26 is then formed over the top surface of the higher k dielectric layer 24. The passivation layer 28 is then formed over the top surface of the lower k dielectric layer 26.

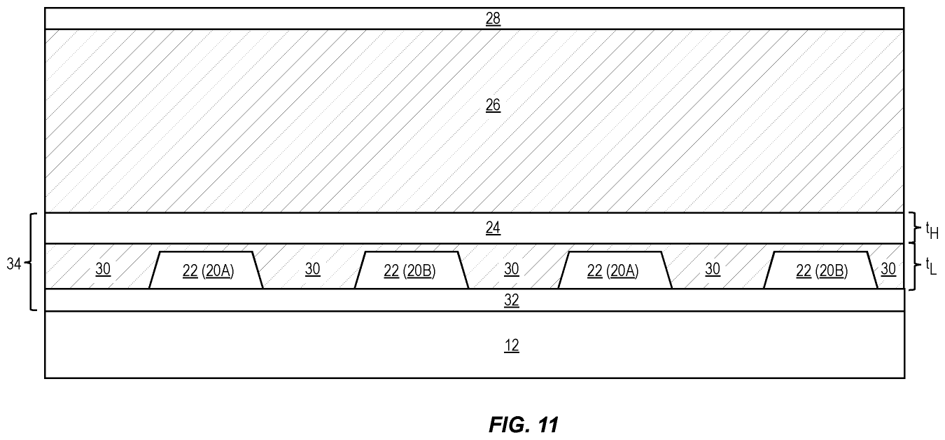

The embodiment of FIG. 11 is similar to the embodiment of FIG. 10, with the exception that the lower k dielectric layer 30 covers the top surfaces of the fingers 22 of the first and second electrodes 20A and 20B. Following formation of the first and second electrodes 20A and 20B, a lower k dielectric layer 30 is deposited over the first and second electrodes 20A and 20B and the exposed surfaces of the higher k dielectric layer 32 that are between the first and second electrodes 20A and 20B. The lower k dielectric layer 30 may be planarized such that the top surface of the lower k dielectric layer 30 remains above the level of the top surface of the first and second electrodes 20A and 20B. The material of the lower k dielectric layer 30 fills in between the fingers 22 of the first and second electrodes 20A and 20B and covers the top surfaces of the first and second electrodes 20A and 20B in this embodiment.

Next, the higher k dielectric layer 24 is formed over the top surface of the lower k dielectric layer 30. Another lower k dielectric layer 26 is then formed over the top surface of the higher k dielectric layer 24. The passivation layer 28 is then formed over the top surface of the lower k dielectric layer 26.

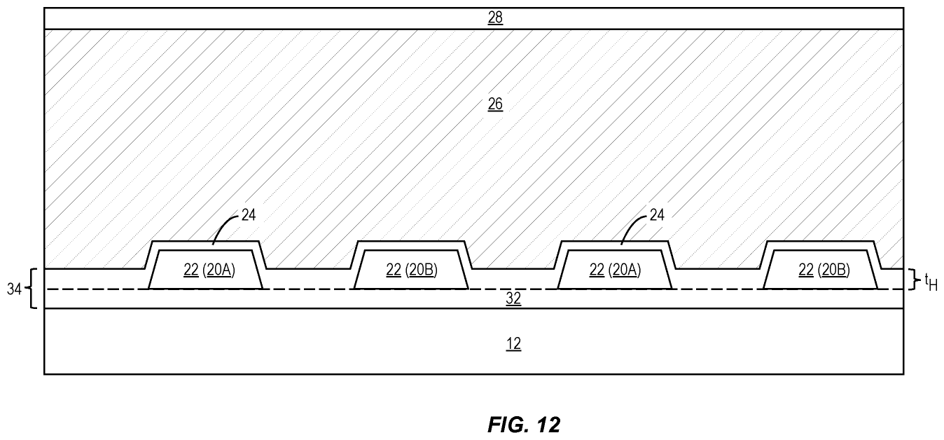

For the embodiment of FIG. 12, another higher k dielectric layer 24 is deposited over the first and second electrodes 20A and 20B and the exposed surfaces of the higher k dielectric layer 32 that are between the first and second electrodes 20A and 20B. At this point, all or at least significant portions of the fingers of the first and second electrodes 20A and 20B are completely or at least substantially encapsulated by the higher k dielectric material of the higher dielectric layers 24, 32, which collectively may be referred to as a composite higher k layer 34. In this embodiment, the higher k dielectric layer 24 is left conformally formed, and thus is not planarized prior to forming the lower k dielectric layer 26 and passivation layer 28 over the higher k dielectric layer 24.

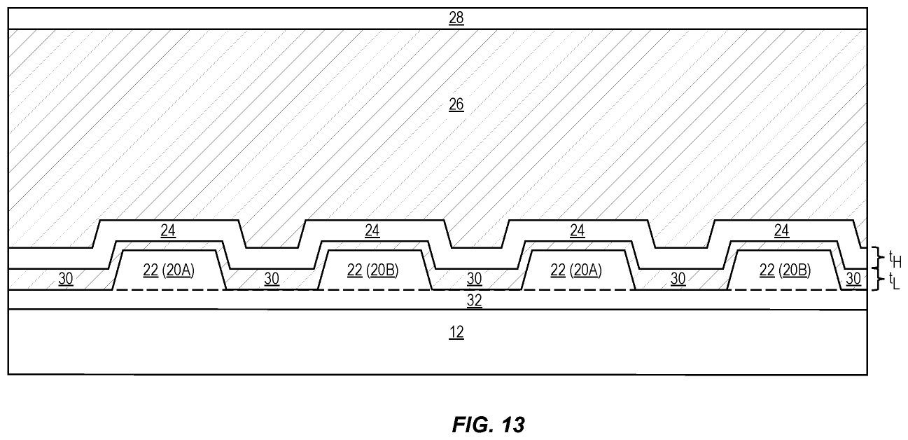

For the embodiment of FIG. 13, a lower k dielectric layer 30 is deposited over the first and second electrodes 20A and 20B and the exposed surfaces of the higher k dielectric layer 32 that are between the first and second electrodes 20A and 20B. Next, a higher k dielectric layer 24 is deposited over the lower k dielectric layer 30. In this embodiment, the lower k dielectric layer 30 and the higher k dielectric layer 24 may be left conformally formed, and thus are not planarized prior to forming the lower k dielectric layer 26 over the higher k dielectric layer 24. In other embodiments, one or both of these layers may be planarized. Finally, the passivation layer 28 is formed over the lower k dielectric layer 26.

For the embodiments described above, lower k dielectric layers 30 may be formed in the same way and with the same materials as previously noted for the lower k dielectric layer 26. The lower k dielectric layers 26 and 30 may be formed from the same or different lower k dielectric materials. The higher k dielectric layer 32 may be formed in the same way and with the same materials as previously noted for the higher k dielectric layer 24. The higher k dielectric layers 24 and 32 may be formed from the same or different higher k dielectric materials.

The concepts disclosed herein address the fundamental limitation for total capacitance of SAW devices 10 that rely solely on lower k dielectric materials, such as SiO₂, for temperature compensation. Simulations of the initial embodiment described above demonstrate significant capacitance increases with the disclosed structure. Corresponding acoustic area shrinks of 15% to more than 45% are demonstrated while maintaining the same device parameters. When using a higher k dielectric material, such as HfO₂, in the temperature compensating layer, the high relative dielectric constant of HfO₂ (k=˜25) vs SiO₂ (k=˜3.9) increases the capacitance per area for resonator-based SAW devices 10. Depositing a lower k dielectric material, such as SiO₂, on top of or below a higher k dielectric material, such as HfO₂, enables temperature compensation without degrading capacitance significantly.

In certain embodiments, the relatively high dielectric constant k of HfO₂ between fingers 22 of the IDT 16 provides additional capacitance as IDT thickness increases. For structures with SiO₂ only, the capacitance is dominated by the piezoelectric substrate 12 (k=˜45 for LiNbO₃) and the impact of IDT thickness is smaller. Providing HfO₂ on the top surface of the electrode contributes additional capacitance, whereas the contribution from SiO₂ is negligible.

Further, the acoustic velocity of HfO₂ is closer to the velocity in the first and second electrodes 20A and 20B of the IDT 16 than that of SiO₂. This reduces the sensitivity of frequency to metal electrode duty factor (DF). Metal electrode duty factor is a main source of process variation during fabrication, so by reducing the sensitivity to DF variability, fabrication process capability can be improved, resulting in increased die yield.

Reduced DF sensitivity also simplifies frequency trimming in N-in-1 (multiple filters and bands on the same die) multiplexing applications by enabling DF to be independent for each filter design. An HfO₂ dielectric implementation can be combined with heavy electrode size reduction techniques (e.g. HM-TCSAW), where heavy metal materials are added in the electrode stack for size reduction by acoustic velocity reduction, for further size reduction.

The concepts provided above may enable size reduction without requirement of velocity reduction by thicker metal and smaller pitch as applied in HM-TCSAW. This reduces process challenges regarding minimum feature sizes and oxide fill of high aspect ratio gaps between the first and second electrodes 20A and 20B.

These concepts may also add a degree of freedom in filter designs to change coupling of single resonators to improve filter performance, e.g. steepen filter skirts individually in low duplex gap applications. The HfO₂ implementation may be selectively applied to individual resonators to tailor trade-offs between performance (TCF, coupling, losses, . . . ) and size optimally for maximized filter performance with the smallest solution size.

Standard TC-SAW using HfO₂ can shift the shear-horizontal (SH) spurious mode (Love mode) to higher frequencies away from antiresonance and thus out of band, which helps regarding passband ripples in small signal and especially can improve large signal behavior and power handling substantially. While HfO₂ is referenced above, the other higher k dielectric materials listed above and known to those skilled in the art will provide the same or similar benefits. HfO₂ is the material used during simulations providing the following plots.

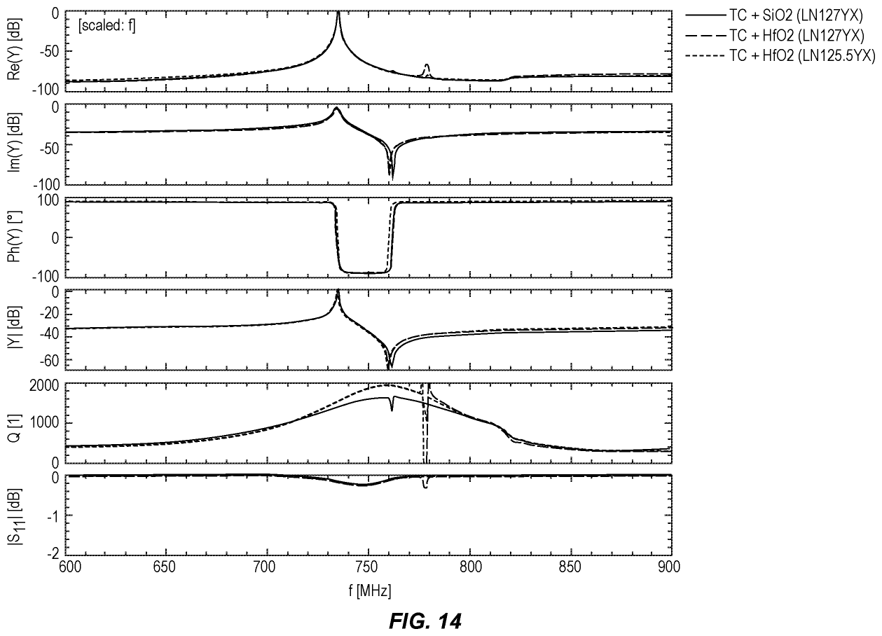

FIG. 14 plots top down real part of admittance Re(Y) (conductance), imaginary part of admittance Im(Y) (susceptance), phase of admittance Ph(Y), absolute value of admittance |Y|, Bode quality factor, and return loss |S₁₁|versus frequency (f) in MHz. The plots show harmonic finite element method (FEM) simulation results of a periodic 2D model for a conventional temperature compensated device with:
an SiO₂ dielectric overcoat on a LN127YX (lithium niobate cut at 127 degrees YX) substrate (solid line) as reference,
HfO₂ as the higher k dielectric layer and SiO₂ as the lower k dielectric layer according to the first embodiment keeping the substrate cut LN127YX (dashed line), and
HfO₂ as the higher k dielectric layer and SiO₂ as the lower k dielectric layer according to the first embodiment rotating the substrate cut to LN125.5YX (lithium niobate cut at 125.5 degrees YX, dotted line). Replacing SiO₂ with HfO₂ results in a shift of the spurious SH mode to higher frequencies (from ˜762 MHz to ˜778 MHz). This can be advantageous in filter designs since passband ripples at the upper band edge are reduced, and power handling capabilities can be improved because the spurious mode is shifted out-of-band. The excitation of this spurious mode is increased when keeping the same substrate cut LN127YX (dashed line), but can be suppressed by rotating the substrate cut to LN125.5YX (dotted line).

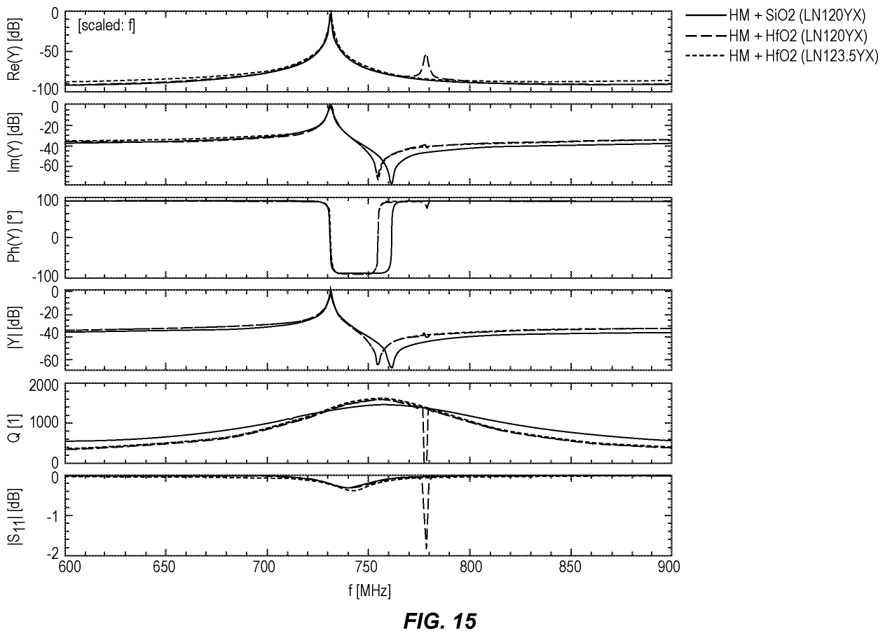

FIG. 15 plots top down real part of admittance Re(Y) (conductance), imaginary part of admittance Im(Y) (susceptance), phase of admittance Ph(Y), absolute value of admittance |Y|, Bode quality factor, and return loss |S₁₁|versus frequency (f) in MHz. FIG. 15 shows harmonic FEM simulation results of a periodic 2D model for a heavy metal type TC-SAW (HM-TCSAW) stack with:
an SiO₂ dielectric overcoat on LN120YX substrate (lithium niobate cut at 120 degrees YX, solid line) as reference,
HfO₂ as the higher k dielectric layer and SiO₂ as the lower k dielectric layer according to the first embodiment keeping the substrate cut LN120YX (dashed line), and
HfO₂ as the higher k dielectric layer and SiO₂ as the lower k dielectric layer according to embodiment 1 rotating the substrate cut to LN123.5YX (lithium niobate cut at 123.5 degrees YX, dotted line).

Replacing SiO₂ with HfO₂ results in a shift of the spurious SH mode from below resonance frequency to above antiresonance frequency (˜778 MHZ). The excitation of this spurious mode is increased when keeping the same substrate cut LN120YX (dashed line) but can be suppressed by rotating the substrate cut to LN123.5YX (dotted line). For details on a heavy metal electrode stack, please refer to U.S. Provisional Patent Application Ser. No. 63/435,083, filed Dec. 23, 2022, which is incorporated herein by reference in its entirety.

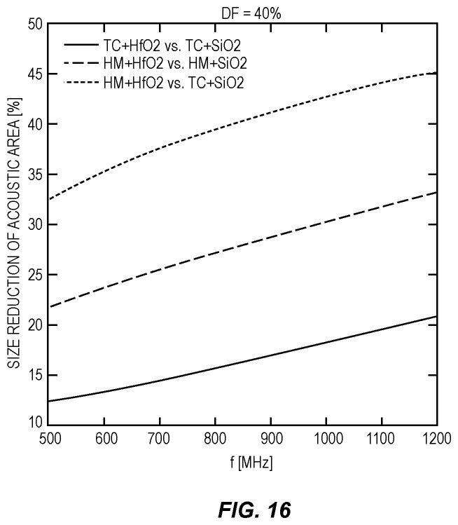

FIG. 16 is a plot of size reduction of acoustic area (%) versus frequency (f) in MHz derived from the results of FIGS. 14 and 15. The plot demonstrates the achieved size reductions of the acoustic area using the first embodiment to realize the same total capacitance for three different scenarios:
1) TC-SAW with HfO₂ instead of SiO₂ (solid line);
2) HM-TCSAW with HfO₂ instead of SiO₂ (dashed line);
3) HM-TCSAW with HfO₂ compared to conventional TC-SAW with SiO₂ (dotted line).

At band 12 (B12) frequency range of the 699-716 MHz uplink, 729-746 MHz downlink (3GPP 36.101) (˜700 MHZ), size reductions of 14.5% for TC-SAW and 25.5% for HM-TCSAW were achieved using the first embodiment of the present disclosure. When comparing HM-TCSAW with HfO₂ overcoat to a current point of reference used for B12 applications, which is conventional TC-SAW using SiO₂ overcoat, the realized size reduction is 37.5%. For higher frequency low band (LB) applications, the potential size reduction is even more as can be seen from the frequency dependence.

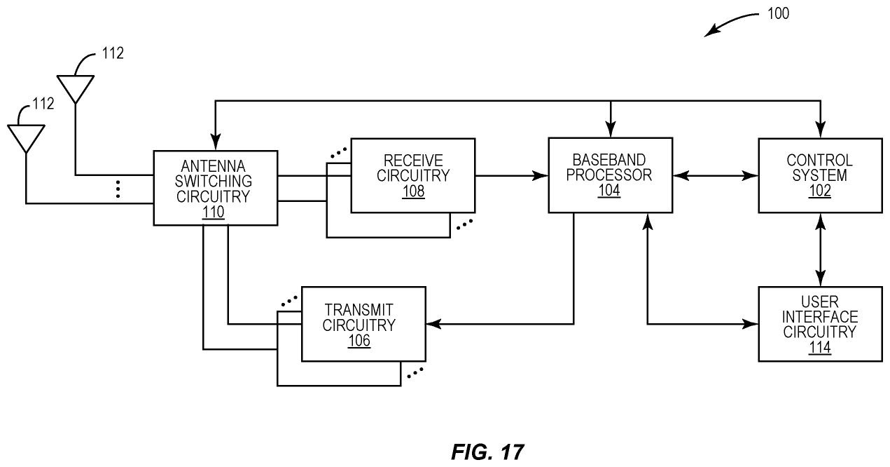

With reference to FIG. 17, the concepts described above may be implemented in various types of user elements 100, such as mobile terminals, smart watches, tablets, computers, navigation devices, access points, and like wireless communication devices that support wireless communications, such as cellular, wireless local area network (WLAN), Bluetooth, and near field communications. The user elements 100 will generally include a control system 102, a baseband processor 104, transmit circuitry 106, receive circuitry 108, antenna switching circuitry 110, multiple antennas 112, and user interface circuitry 112. In a non-limiting example, the control system 102 may be a field-programmable gate array (FPGA) or an application-specific integrated circuit (ASIC). In this regard, the control system 102 may include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter of the receive circuitry 108 cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed on greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal through the antenna switching circuitry 110 to the antennas 112. The multiple antennas 112 and the replicated transmit and receive circuitries 106, 108 may provide spatial diversity. Modulation and processing details will be understood by those skilled in the art. The SAW devices 10 are particularly useful in the filters, duplexers, and N-in-1 multiplexers that may be provided in the antenna switching circuitry 110, receive circuitry 108, and/or transmit circuitry 106.

Those skilled in the art will recognize improvements and modifications to the preferred embodiments of the present disclosure. All such improvements and modifications are considered within the scope of the concepts disclosed herein and the claims that follow.

What is claimed is:

1. A surface acoustic wave (SAW) device, comprising:
a piezoelectric substrate;
an interdigitated transducer (IDT) over a top surface of the piezoelectric substrate and comprising first and second electrodes with interdigitated fingers;
a first higher k dielectric layer over the IDT; and
a first lower k dielectric layer over the first higher k dielectric layer, wherein a dielectric constant of first higher k dielectric layer is higher than a dielectric constant of the first lower k dielectric layer.

2. The SAW device of claim 1 wherein first portions of the first higher k dielectric layer reside between adjacent ones of the interdigitated fingers of the first and second electrodes.

3. The SAW device of claim 1 wherein first portions of the first higher k dielectric layer reside over the interdigitated fingers of the first and second electrodes, and second portions of the first higher k dielectric layer reside between adjacent ones of the interdigitated fingers of the first and second electrodes.

4. The SAW device of claim 3 wherein a top surface of the first higher k dielectric layer is planar.

5. The SAW device of claim 3 wherein a top surface of the first higher k dielectric layer is not planar and conformally covers the IDT.

6. The SAW device of claim 5 further comprising a second higher k dielectric layer over the top surface of the piezoelectric substrate wherein:
the IDT and the first higher k dielectric layer reside over the second higher k dielectric layer, and
a dielectric constant of the second higher k dielectric layer is higher than the dielectric constant of the first lower k dielectric layer.

7. The SAW device of claim 3 further comprising a second higher k dielectric layer over the top surface of the piezoelectric substrate wherein:
the IDT and the first higher k dielectric layer reside over the second higher k dielectric layer, and
a dielectric constant of the second higher k dielectric layer is higher than the dielectric constant of the first lower k dielectric layer.

8. The SAW device of claim 1 further comprising a second lower k dielectric layer between the top surface of the piezoelectric substrate and the first higher k dielectric layer wherein:
first portions of the first higher k dielectric layer reside over the interdigitated fingers of the first and second electrodes, and first portions of the second lower k dielectric layer reside between adjacent ones of the interdigitated fingers of the first and second electrodes, and
the dielectric constant of the first higher k dielectric layer is higher than a dielectric constant of the second lower k dielectric layer.

9. The SAW device of claim 8 further comprising a second higher k dielectric layer over the top surface of the piezoelectric substrate wherein:
the IDT, the second lower k dielectric layer, and the first higher k dielectric layer reside over the second higher k dielectric layer, and
a dielectric constant of the second higher k dielectric layer is higher than the dielectric constant of the first lower k dielectric layer.

10. The SAW device of claim 8 wherein second portions of the second lower k dielectric layer reside over the interdigitated fingers of the first and second electrodes.

11. The SAW device of claim 10 wherein a top surface of the second lower k dielectric layer is planar.

12. The SAW device of claim 11 wherein a top surface of the first higher k dielectric layer is planar.

13. The SAW device of claim 10 further comprising a second higher k dielectric layer over the top surface of the piezoelectric substrate wherein:
the IDT, the second lower k dielectric layer, and the first higher k dielectric layer reside over the second higher k dielectric layer, and
a dielectric constant of the second higher k dielectric layer is higher than the dielectric constant of the first lower k dielectric layer.

14. The SAW device of claim 8 wherein a top surface of the second lower k dielectric layer is not planar and conformally covers the IDT.

15. The SAW device of claim 14 further comprising a second higher k dielectric layer over the top surface of the piezoelectric substrate wherein:
the IDT, the second lower k dielectric layer, and the first higher k dielectric layer reside over the second higher k dielectric layer, and
a dielectric constant of the second higher k dielectric layer is higher than the dielectric constant of the first lower k dielectric layer.

16. The SAW device of claim 14 wherein a top surface of the first higher k dielectric layer is not planar and conformally covers the second lower k dielectric layer.

17. The SAW device of claim 1 wherein the first higher k dielectric layer comprises hafnium oxide (HfO₂).

18. The SAW device of claim 17 wherein the first lower k dielectric layer comprises silicon dioxide (SiO₂).

19. The SAW device of claim 1 wherein the dielectric constant of first higher k dielectric layer is greater than 4, and the dielectric constant of the first lower k dielectric layer is less than 4.

20. The SAW device of claim 1 wherein the dielectric constant of first higher k dielectric layer is greater than 10, and the dielectric constant of the first lower k dielectric layer is less than 4.

21. The SAW device of claim 1 wherein the dielectric constant of first higher k dielectric layer is greater than 24, and the dielectric constant of the first lower k dielectric layer is less than 4.

22. The SAW device of claim 1 wherein the dielectric constant of first higher k dielectric layer is greater than 24.

23. The SAW device of claim 1 wherein the first higher k dielectric layer comprises at least one of hafnium oxide, silicon nitride, yttrium oxide, zirconium oxide, lanthanum oxide, tantalum oxide, titanium oxide, and aluminum oxide.

24. A surface acoustic wave (SAW) device, comprising:
a piezoelectric substrate;
a first higher k dielectric layer over the piezoelectric substrate;
an interdigitated transducer (IDT) over a top surface of the first higher k dielectric layer and comprising first and second electrodes with interdigitated fingers;
a first lower k dielectric layer over the first higher k dielectric layer and the IDT, wherein a dielectric constant of first higher k dielectric layer is higher than a dielectric constant of the first lower k dielectric layer.

25. A method of fabricating a surface acoustic wave (SAW) device, comprising:
providing a piezoelectric substrate;
forming an interdigitated transducer (IDT) over a top surface of the piezoelectric substrate and comprising first and second electrodes with interdigitated fingers;
forming a first higher k dielectric layer over the IDT; and
forming a first lower k dielectric layer over the first higher k dielectric layer, wherein a dielectric constant of first higher k dielectric layer is higher than a dielectric constant of the first lower k dielectric layer.
